(19) United States
(12) Patent Application Publication
(10) Pub. No.: US 2013/0178055 A1
(43) Pub. Date: Jul. 11, 2013

(54) Methods of Forming a Replacement Gate Electrode With a Reentrant Profile

(71) Applicants: Andre P. LaBonte, Scarborough, ME (US); Phillip L. Jones, Fremont, CA (US)

(72) Inventors: Andre P. LaBonte, Scarborough, ME (US); Phillip L. Jones, Fremont, CA (US)

(73) Assignee: GLOBALFOUNDRIES INC., Grand Cayman (KY)

(21) Appl. No.: 13/345,879

(22) Filed: Jan. 9, 2012

(51) Int. Cl. H01L 21/28; H01L 21/283

(52) U.S. Cl. 438/595; 438/585; 257/E21.19; 257/E21.159

(57) ABSTRACT

Disclosed herein are methods of forming a replacement gate structure having a reentrant profile. In one example, the method includes forming a layer of material for a sacrificial gate electrode, wherein the layer of material includes at least one impurity that changes the etch rate of the layer of material as compared to an etch rate for the layer of material without the impurity, and wherein a concentration of the at least one impurity varies along a direction that corresponds to a thickness of the layer of material, and performing another etching process on the layer of material to define a sacrificial gate electrode. The method concludes with the steps of performing another etching process to remove the sacrificial gate electrode so as to at least partially define a gate opening in a layer of insulating material and forming a replacement gate structure in the gate opening.

### BACKGROUND OF THE INVENTION

1. Field of the Invention

The present disclosure generally relates to the manufacturing of sophisticated semiconductor devices, and, more specifically, to various methods of forming various replacement gate electrodes having a reentrant profile.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NMOS and PMOS transistors) represent one important type of circuit element that substantially determines performance of the integrated circuits. During the fabrication of complex integrated circuits using, for instance, MOS technology, millions of transistors, e.g., NMOS transistors and/or PMOS transistors, are formed on a substrate including a crystalline semiconductor layer. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, such as a channel region, disposed between the highly doped source/drain regions.

In a field effect transistor, the conductivity of the channel region, i.e., the drive current capability of the conductive channel, is controlled by a gate electrode formed above the channel region and separated therefrom by a thin gate insulation layer. The conductivity of the channel region, upon formation of a conductive channel due to the application of an appropriate control voltage to the gate electrode, depends on, among other things, dopant concentration, the mobility of the charge carriers and, for a given extension of the channel region in the transistor width direction, on the distance between the source and drain regions, which is also referred to as the channel length of the transistor. Thus, since the speed of creating the channel, which depends in part on the conductivity of the gate electrode, and the channel resistivity substantially determine the characteristics of the transistor, the scaling or reduction of the channel length, and associated therewith the reduction of channel resistivity and the increase of gate resistivity, are dominant design efforts used to increase the operating speed of integrated circuits using such transistors.

For many early device technology generations, the gate electrode structures of most transistor elements have been comprised of silicon-based materials, such as a silicon dioxide and/or silicon oxynitride gate insulation layer, in combination with a polysilicon gate electrode. However, as the channel length of aggressively scaled transistor elements has become increasingly smaller, many newer generation devices employ gate electrode stacks comprising alternative materials in an effort to avoid the short-channel effects which may be associated with the use of traditional silicon-based materials in reduced channel length transistors. For example, in some aggressively scaled transistor elements, which may have channel lengths on the order of approximately 14-32 nm, gate electrode stacks comprising a so-called high-k dielectric/metal gate (HK/MG) configuration have been shown to provide significantly enhanced operational characteristics over the heretofore more commonly used silicon dioxide/polysilicon (SiO/poly) configurations.

Depending on the specific overall device requirements, several different high-k materials—i.e., materials having a dielectric constant, or k-value, of approximately 10 or greater—have been used with varying degrees of success for the gate insulation layer in a HK/MG gate electrode structure. For example, in some transistor element designs, a high-k gate insulation layer may include tantalum oxide (Ta₂O₅), hafnium oxide (HfO₂), zirconium oxide (ZrO₂), titanium oxide (TiO₂), aluminum oxide (Al₂O₃), hafnium silicates (HfSiOₓ) and the like. Furthermore, one or more non-polysilicon metal gate electrode materials—i.e., a metal gate stack—may be used in HK/MG configurations so as to control the work function of the transistor. These metal gate electrode materials may include, for example, one or more layers of titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi) and the like.

One well-known processing method that has been used for forming a transistor with a high-k/metal gate structure is the so-called “gate last” or “replacement gate” technique. FIGS. 1A-1D depict one illustrative prior art method for forming an illustrative HK/MG replacement gate structure using a gate-last technique. As shown in FIG. 1A, the process includes the formation of a basic transistor structure 100 above a semiconducting substrate 10 in an active area defined by a shallow trench isolation structure 11. At the point of fabrication depicted in FIG. 1A, the device 100 includes a sacrificial gate insulation layer 12, a dummy or sacrificial gate electrode 14, sidewall spacers 16, a layer of insulating material 17 and source/drain regions 18 formed in the substrate 10. It will be recognized by those skilled in the art that the sidewall spacers 16 may not be employed in all applications but, for purposes of explanation, the sidewall spacers 16 will be depicted in FIGS. 1A-1D.

The various components and structures of the device 100 may be formed using a variety of different materials and by performing a variety of known techniques. For example, the sacrificial gate insulation layer 12 may be comprised of silicon dioxide, the sacrificial gate electrode 14 may be comprised of polysilicon, the sidewall spacers 16 may be comprised of silicon nitride and the layer of insulating material 17 may be comprised of silicon dioxide. The source/drain regions 18 may be comprised of implanted dopant materials (N-type dopants for NMOS devices and P-type dopants for PMOS devices) that are implanted into the substrate using known masking and ion implantation techniques. Of course, those skilled in the art will recognize that there are other features of the transistor 100 that are not depicted in the drawings for purposes of clarity. For example, so-called halo implant regions are not depicted in the drawings, as well as various layers or regions of silicon germanium that are typically found in high-performance PMOS transistors. At the point of fabrication depicted in FIG. 1A, the various structures of the device 100 have been formed and a chemical mechanical polishing process (CMP) has been performed to remove any materials above the sacrificial gate electrode 14 (such as a protective cap layer (not shown) comprised of silicon nitride) so that the sacrificial gate electrode 14 may be exposed and subsequently removed.

As shown in FIG. 1B, one or more etching processes are performed to remove the sacrificial gate electrode 14 and the sacrificial gate insulation layer 12 to thereby define a gate opening 20 where a replacement gate structure will subsequently be formed. A masking layer that is typically used in such etching processes is not depicted for purposes of clarity. Typically, the sacrificial gate insulation layer 12 is removed as part of the replacement gate technique, as depicted herein. However, the sacrificial gate insulation layer 12 may not be removed in all applications.

Next, as shown in FIG. 1C, various layers of material that will constitute a replacement gate structure 30 are formed in the gate opening 20. In one illustrative example, the replacement gate structure 30 is comprised of a high-k gate insulation layer 30A having a thickness of approximately 2 nm, a work-function adjusting layer 30B comprised of a metal (e.g., a layer of titanium nitride with a thickness of 2-5 nm) and a bulk metal layer 30C (e.g., aluminum). Ultimately, as shown in FIG. 1D, a CMP process is performed to remove excess portions of the gate insulation layer 30A, the work-function adjusting layer 30B and the bulk metal layer 30C positioned outside of the gate opening 20 to define the replacement gate structure 30.

FIGS. 1E-1F depict various profiles of the sacrificial gate electrode 14 that are typically encountered in device manufacturing. In FIG. 1E, the sacrificial gate electrode 14 has a generally rectangular cross-sectional configuration, much like the sacrificial gate electrode depicted in FIGS. 1A-1D, wherein the upper surface 14U of the sacrificial gate electrode 14 has substantially the same width as the lower surface 14L of the sacrificial gate electrode 14. In FIG. 1F, the sacrificial gate electrode 14 has an outwardly-flaring or outwardly tapered cross-sectional configuration, i.e., the width of the sacrificial gate electrode 14 is less at the upper surface 14U than at the lower surface 14L. Stated another way, the width of the sacrificial gate electrode 14 increases as one progresses from the upper surface 14U to the lower surface 14L of the sacrificial gate electrode 14. FIG. 1G depicts an illustrative rectangular sacrificial gate electrode 14 that exhibits examples of undesirable footing 21 and notching 23. Such footing and notching may result from a variety of factors, such as imperfect etching processes. Moreover, such footing or notching may also occur in sacrificial gate electrodes 14 having the outwardly-flaring cross-sectional configuration depicted in FIG. 1F, although such footing and notching are not depicted in the drawings.

FIG. 1H depicts an illustrative gate opening 20 that has been created after a sacrificial gate electrode 14 having an outwardly flaring cross-sectional configuration, like that shown in FIG. 1F, has been removed. Obviously, the cross-sectional configuration gate opening 20 is the same as that of the sacrificial gate electrode 14. That is, in this example, the width of the gate opening 20 at the top is smaller than the width at the bottom of the gate opening 20. Such a configuration in the gate opening 20 may lead to problems as it relates to the formation of a replacement gate structure in the gate opening 20. Moreover, the outwardly flaring configuration of the sacrificial gate electrode 14 may tend to inhibit complete removal of the sacrificial gate electrode 14 and/or the sacrificial gate insulation layer 12.

After the gate opening in FIG. 1H is formed, one or more deposition processes 25 are performed to form the various layers that will constitute the replacement gate structure, such as the illustrative high-k gate insulation layer 30A, the work-function adjusting layer 30B comprised of a metal and the bulk metal layer 30C depicted in FIG. 1C for the illustrative replacement gate structure 30. In particular, one or more physical vapor deposition (PVD) processes are typically performed to form the metal layers that will be part of the final replacement gate electrode structure. In general, a PVD process is predominately a directional deposition process, although a PVD process may include some non-directional, chemical deposition aspects as well. Due to the configuration of the gate opening 20, there may be some shadowing within the areas 27. The shadowing of at least the sidewalls of the gate opening 20 during the PVD processes may result in incomplete formation of one or more of the metal layers and, in some cases, may result in the creation of voids within the replacement gate structure. Such defects may lead to reduced device performance or perhaps complete failure in a worst-case scenario. Such shadowing may also be present in the case where the gate opening 20 is formed by removing a sacrificial gate electrode 14 having a generally rectangular cross-sectional configuration, like the one depicted in FIG. 1E, although the shadowing effects may be less pronounced than those encountered when the gate opening 20 has the outwardly-tapered configuration depicted in FIG. 1H. Additionally, undesirable footing and/or notching of the sacrificial gate electrode 14 may also be reflected in the configuration of the gate opening 20 when the sacrificial gate electrode 14 is removed, although the effects of such footing and/or notching are not depicted in the opening 20 shown in FIG. 1H. To the extent the gate opening 20 reflects footing and/or notching problems that exist on the sacrificial gate electrode 14, the problems identified above may be increased.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is generally directed to various methods of forming replacement gate electrodes having a reentrant profile. In one example, the method includes forming a layer of material for a sacrificial gate electrode, wherein the layer of material includes at least one impurity that changes the etch rate of the layer of material as compared to an etch rate for the layer of material without the impurity, and wherein the concentration of the at least one impurity varies along a direction that corresponds to a thickness of the layer of material, and performing another etching process on the layer of material to define a sacrificial gate electrode. The method concludes with the steps of performing another etching process to remove the sacrificial gate electrode so as to at least partially define a gate opening in a layer of insulating material and forming a replacement gate electrode in the gate opening. Depending upon the materials and the technique selected, the impurity may either increase or decrease the etch rate of the layer of material as compared to an etch rate for the layer of material without the impurity.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1H depict one illustrative prior art process flow for forming a semiconductor device using a gate last approach; and

FIGS. 2A-2I depict various illustrative examples of using the methods of forming various replacement gate electrodes having a reentrant profile.

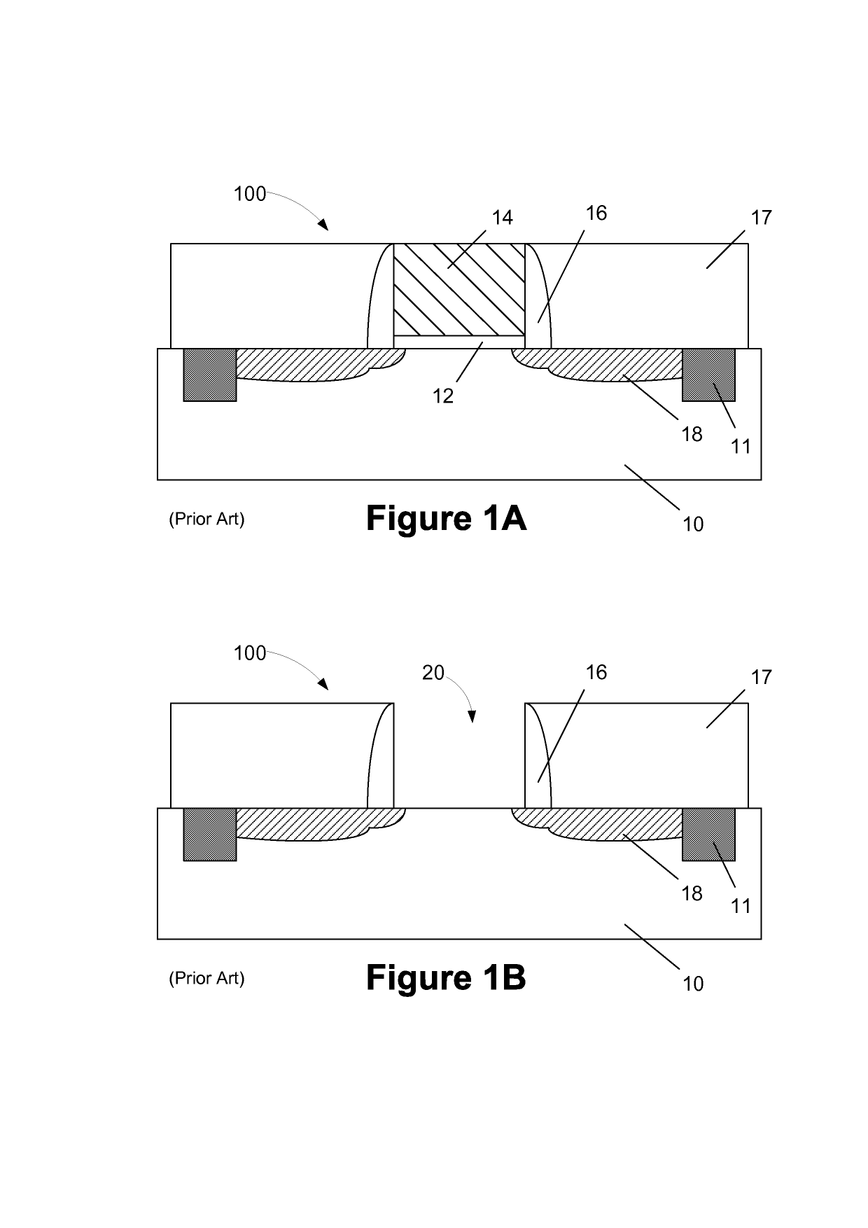

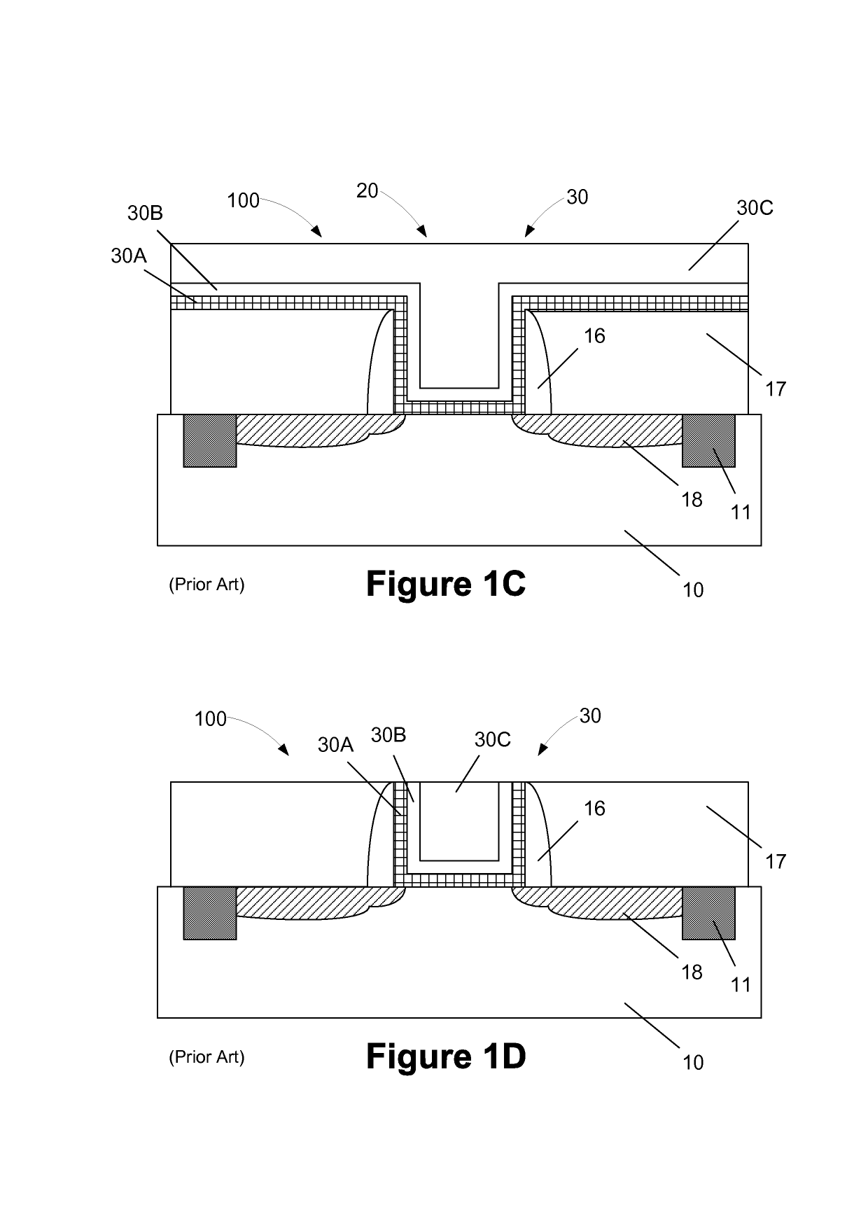

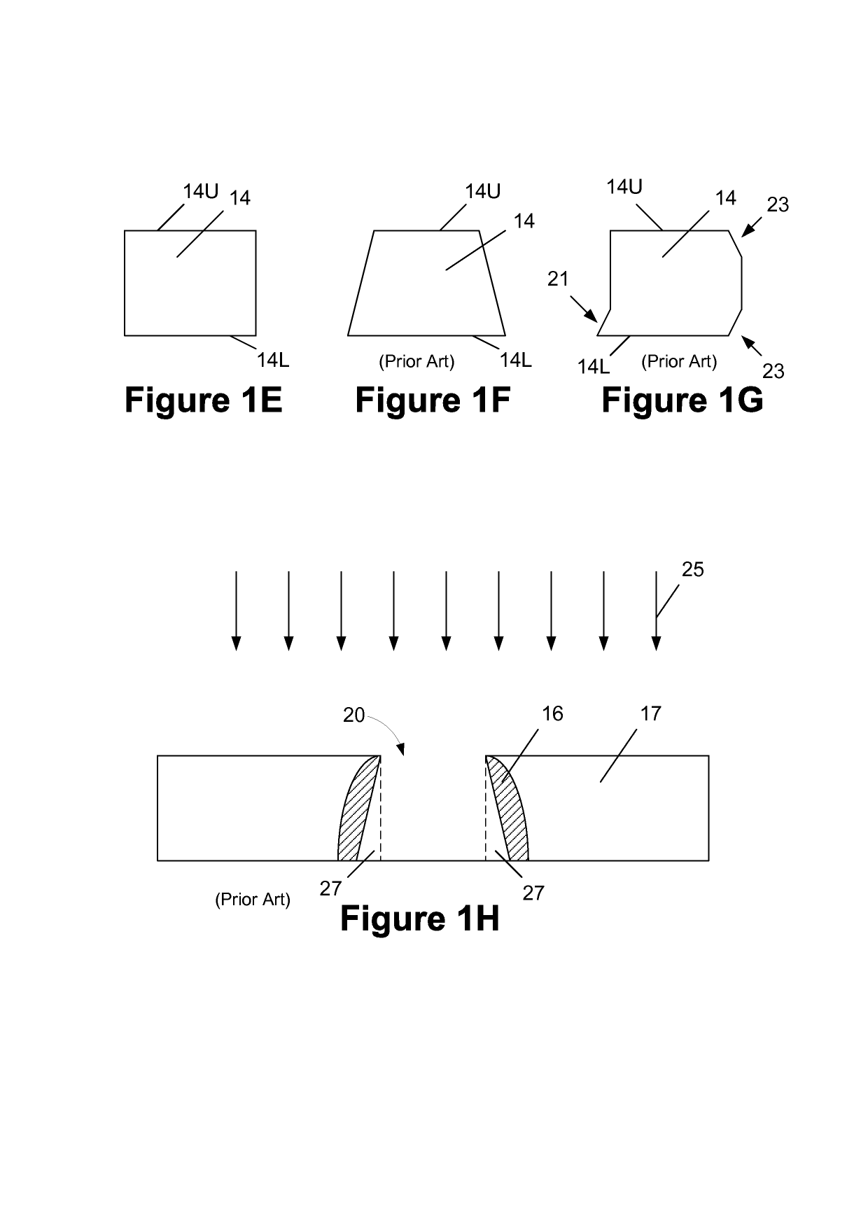

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

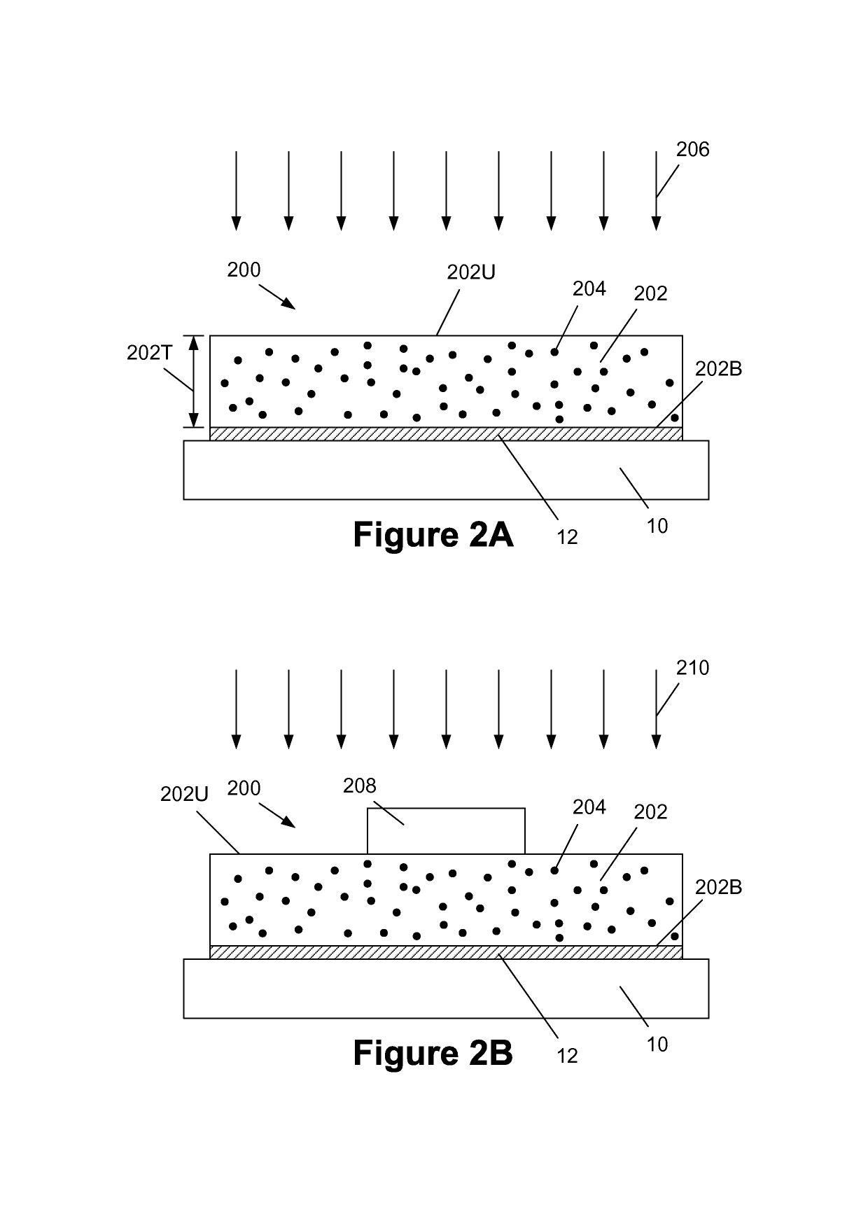

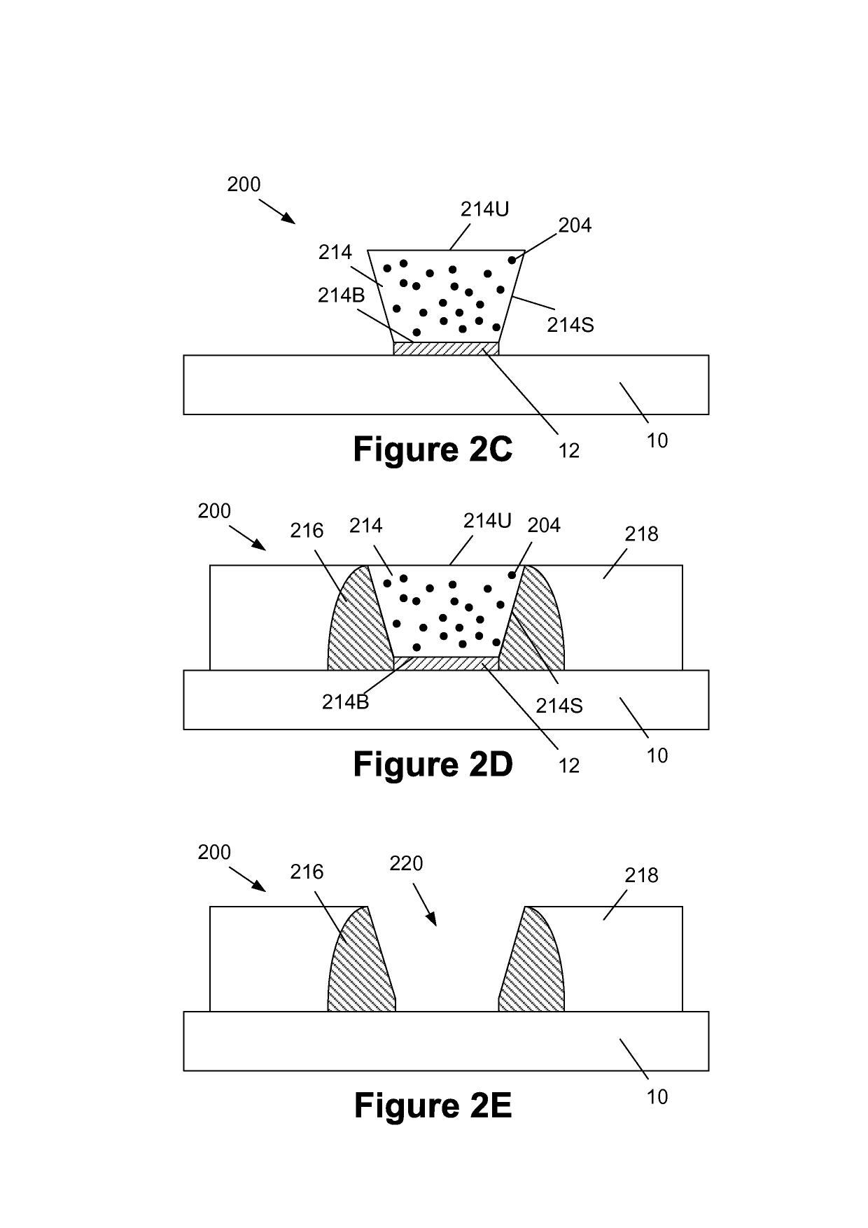

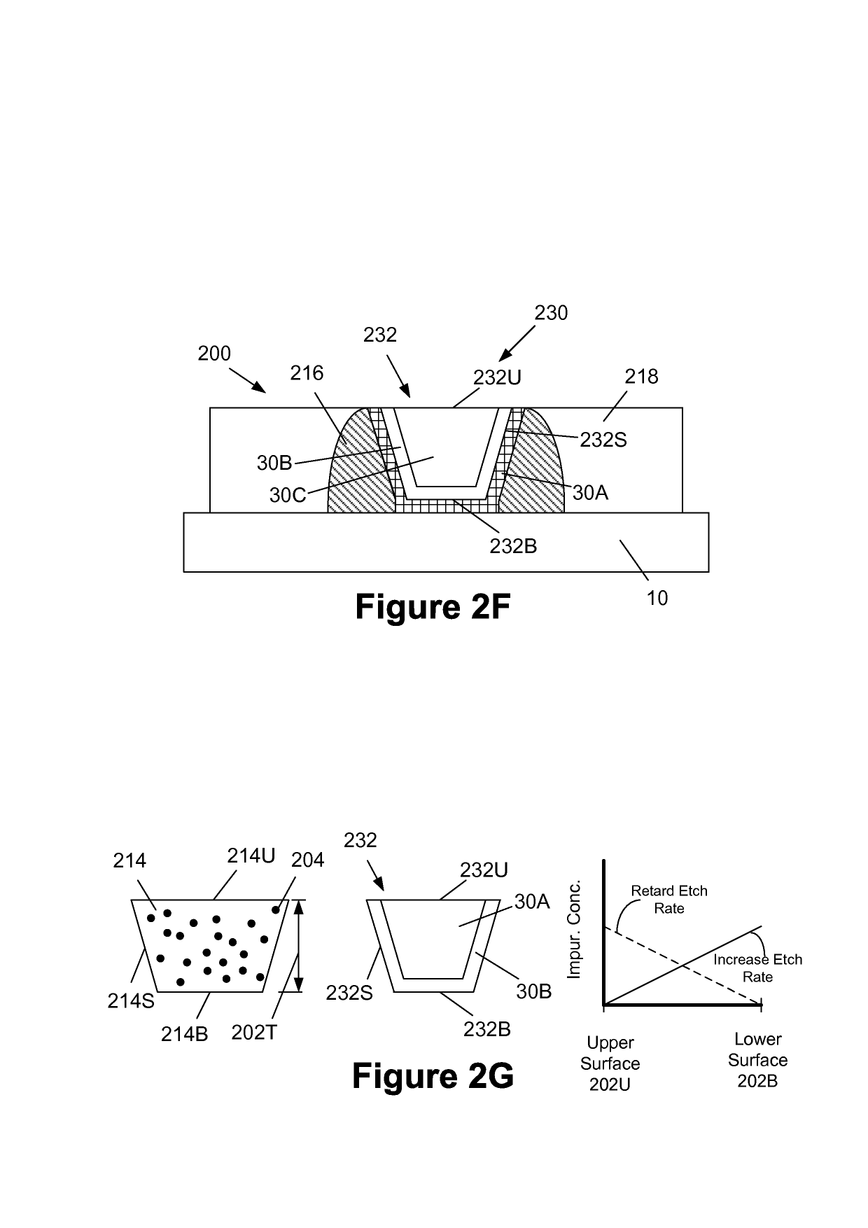

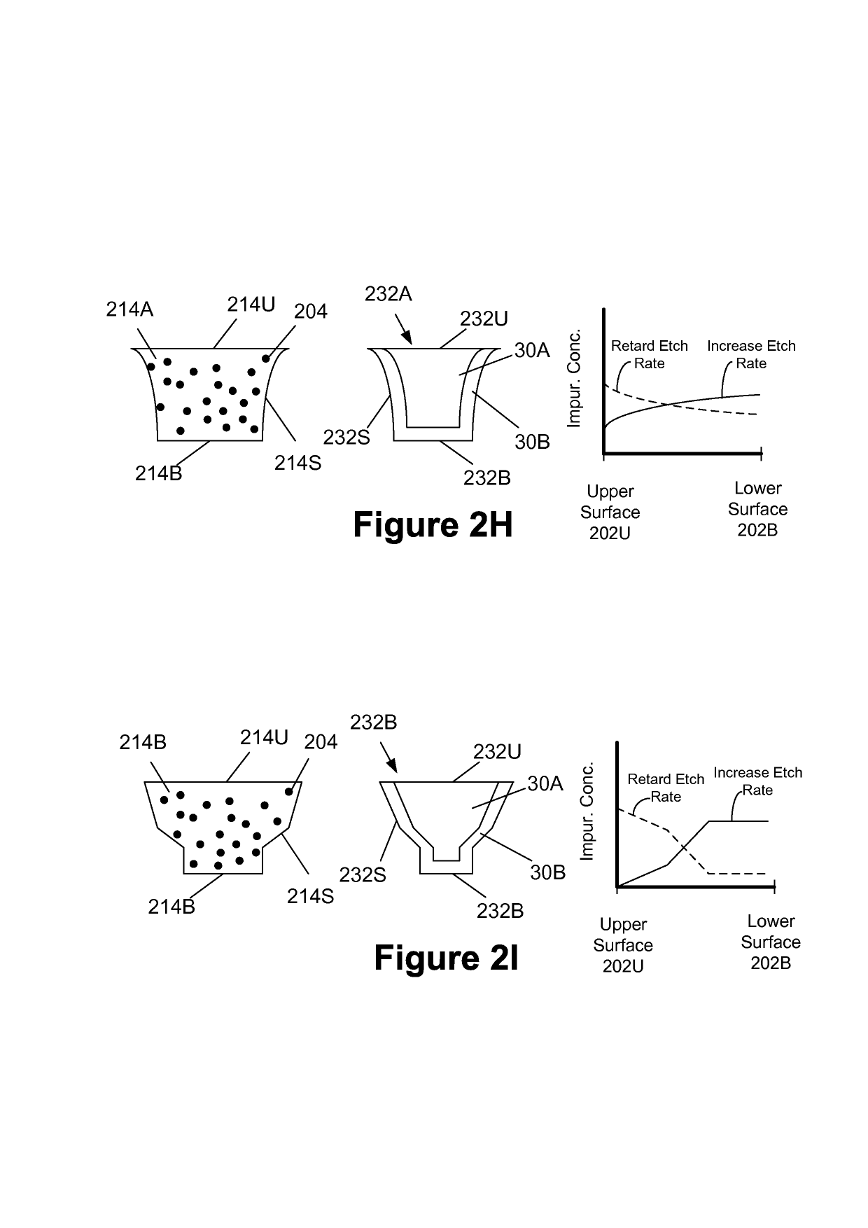

In general, the present disclosure is directed to various methods of forming replacement gate electrodes that have a reentrant profile. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, logic devices, memory devices, etc. With reference to FIGS. 2A-2I, various illustrative embodiments of the methods and devices disclosed herein will now be described in more detail. Of course, to the extent that like numbers of various components are used, the previous discussion of those components in connection with the device 100 applies equally as well to the device and methods described below.

FIG. 2A is a simplified view of an illustrative semiconductor device 200 at an early stage of manufacturing. The semiconductor device 200 is formed above a semiconducting substrate 10. At the point of fabrication depicted in FIG. 2A, the device 200 includes a sacrificial gate insulation layer 12 and a layer of material 202 having schematically depicted impurity or impurities 204 therein. The impurity or impurities 204 may be introduced into the layer of material 202 by performing one of a variety of different schematically depicted processes 206, as will be discussed more fully below. Although not depicted in the attached drawings, there may be one or more additional layers of material formed above the layer of material 202, such as, for example, a layer of silicon nitride. Such additional layers, to the extent that they may be present, are not depicted so as not to obscure the present inventions. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 10 may also be made of materials other than silicon.

The sacrificial gate insulation layer 12 may be comprised of a variety of materials, such as silicon dioxide, and it may be formed by performing any of a variety of known techniques, a chemical vapor deposition (CVD) process, a thermal growth process, etc. As will be recognized by those skilled in the art after a complete reading of the present application, the layer of material 202 will be used to manufacture a sacrificial gate electrode for the device 200. Eventually, the sacrificial gate electrode will be removed and a replacement gate electrode will be formed in its place. The layer of material 202 may be comprised of a variety of different materials, such as silicon, doped silicon, silicon-germanium, gallium arsenide, etc., and it may be formed by performing a variety of known techniques, a CVD process, an epitaxial deposition process, etc. Moreover, the thickness 202T of the layer of material 202 may vary depending upon the particular application, e.g., in one illustrative embodiment, for current-day technologies, it may have a thickness 202T ranging from approximately 40-500 nm depending on the particular application.

The impurity atoms 204 may be introduced into the layer of material 202 by a variety of techniques, which are schematically represented by the arrows 206. In one illustrative example, the impurity or impurities 204 may be introduced into a process chamber—in situ—as the layer of material 202 is being formed. In another example, the layer of material 202 may be initially formed without the impurities 204 and an ion implantation process or a diffusion process may be performed to introduce the impurities 204 into the layer 202. Thus, the particular technique by which the impurities 204 may be introduced into the layer of material 202 should not be considered a limitation of the presently disclosed subject matter. In some cases, depending upon the techniques selected to introduce the impurities 204 into the layer 202, a masking layer (not shown) may be employed such that the impurities 204 are only formed in certain locations of the layer of material 202.

In general, depending upon the material of the layer 202 and the specific impurities or dopants 204 added to the layer 202, the etch rate of the layer of material 202 in the lateral or horizontal direction, i.e., in a direction that is generally parallel to the upper surface of the substrate 10, may be increased or decreased as compared to an etch rate for the layer of material 202 without the impurity 204. The particular impurity or impurities 204 selected may vary depending on the particular application. For example, the impurities or dopants 204 may be any of the impurities or dopants that are commonly used in semiconductor processing, such as, for example, germanium, arsenic, indium, phosphorous, boron, carbon, etc., or combinations of such impurities. As noted, in some cases, only a single species of impurity, such as germanium, may be used. In one particularly illustrative example, the layer of material 202 is a layer of silicon germanium that is formed in an epitaxial deposition process, wherein germanium is introduced in situ during the process.

In one illustrative embodiment, the concentration of the impurity or impurities 204 increases in a direction that corresponds to the thickness 202T of the layer 202, in a direction that is approximately normal to the surface of the substrate 10. Stated another way, in one embodiment, the concentration of the impurities 204 is greater near a bottom surface 202B of the layer of material 202 than the concentration of impurities near the upper surface 202U of the layer of material 202. In this illustrative embodiment, the impurity enhances or increases the etch rate of the layer of material 202 as compared to an etch rate for the layer of material 202 without the impurity 204, thereby leading to the desired reentrant profile. The variation in the concentration of the impurities 204 along the thickness direction may be linear or non-linear depending upon the desired final shape of the sacrificial gate electrode and, ultimately, the desired final shape of the replacement gate electrode, as discussed more fully below. It should be understood that the depiction of the impurities 204 in the layer of material 202 is representative only and it is not meant to imply or suggest any particular distribution or concentration of the impurities 204 within the layer of material 202.

In another illustrative embodiment, the concentration of the impurity or impurities 204 decreases in a direction that corresponds to the thickness 202T of the layer 202, in a direction that is approximately normal to the surface of the substrate 10. Stated another way, in one embodiment, the concentration of the impurities 204 is less near a bottom surface 202B of the layer of material 202 than the concentration of impurities near the upper surface 202U of the layer of material 202. In this illustrative embodiment, the presence of the impurity atoms 204 decreases the etch rate of the layer of material 202 as compared to an etch rate for the layer of material 202 without the impurity 202. For example, a layer of silicon containing implanted carbon impurities tends to etch at a slower rate than a layer of silicon without such implanted carbon impurities. Thus, performing an etching process on a layer of silicon with a higher concentration of carbon atoms near the upper surface of the layer of silicon than at the bottom of the layer of silicon will produce the desired reentrant profile for the sacrificial gate electrode 214.

Next, as shown in FIG. 2B, a masking layer 208, e.g., a patterned photoresist mask, is formed above the layer of material 202, and an illustrative etching process 210 is performed on the exposed portions of the layer of material 202. The etching process 210 may be either a wet or dry etching process and the etch chemistry employed may vary depending upon the particular application. In the illustrative example where the layer of material is a layer of silicon with germanium impurities 204 therein, the etching process 210 may be a chlorine or fluorine based dry etching process.

Performing the etching process 210 results in the definition of a sacrificial gate electrode 214 having a reentrant or inwardly-tapered cross-sectional configuration, as shown in FIG. 2C. Stated another way the width of the sacrificial gate electrode 214 at its bottom surface 214B is less than the width of the sacrificial gate electrode 214 at its upper surface 214U. In the illustrative example depicted in FIG. 2C the sidewalls 214S of the sacrificial gate electrode 214 have a generally planar and an inwardly-tapered configuration. As will be described more fully below, the cross-sectional configuration of the sacrificial gate electrode 214 may be controlled by controlling the distribution of the impurities 204 within the layer of material 202 and by controlling the etching process 210. More specifically, by controlling the etch process 210 and by using the appropriate etch chemistry, the etch rate-enhancing or etch rate-retardant effects of the impurities 204 (depending upon which technique is selected) on the layer of material 202 may be emphasized to produce the desired reentrant profile for the sacrificial gate electrode 214. It should be noted that an additional etch process, with a different etch chemistry, may be performed to remove the undesirable portions of the sacrificial gate insulation layer 12 after the etching process 210 is performed.

Next, as shown in FIG. 2D, the process continues with basic “gate-last” processing techniques including the formation of one or more insulating materials adjacent the sacrificial gate electrode 214. More specifically, in the depicted embodiment, a sidewall spacer 216 and a layer of insulating material 218 are formed using traditional techniques. For example, the sidewall spacer 216 may be comprised of a variety of insulating materials, such as silicon nitride, and it may be formed by depositing a layer of spacer material and performing an anisotropic etching process. The layer of insulating material may also be comprised of a variety of materials, e.g., silicon dioxide, and it may be formed by performing a CVD process. Of course, depending upon the particular application, there may be additional sidewall spacers formed adjacent the sidewall spacer 216 and there may be cases where no sidewall spacer is formed. Thus, when it is stated in the claims that the sacrificial gate electrode 214 or a gate opening 220 (discussed below) is formed, defined or positioned in a “layer comprised of insulating material,” such language shall be understood to mean that one or more insulating materials, in whatever shape or form, are formed adjacent the sacrificial gate electrode 214. This includes the situation where one or more sidewall spacers are present and situations where there are no sidewall spacers present. It also includes situations where there may be single or multiple materials that are part of the “layer comprised of insulating material.” As with the discussion of the prior art device 100 in the background section of this application, there are, of course, many aspects of the transistor device 200 that are not depicted in the drawings so as not to obscure the present invention. For example, prior to the formation of the sidewall spacer 216 and the layer of insulating material 218, one or more doped regions, e.g., source/drain regions, halo implant regions, etc., may be formed in the substrate 10 by performing known techniques. However, such doped regions are not depicted in the drawings so as not to obscure the present invention. Additionally, one or more protective cap layers (not shown) are typically formed over the sacrificial gate electrode 214 to protect the sacrificial gate electrode 214 from various process operations until it is time to remove the sacrificial gate electrode 214.

Next, the device 200 is at the point in “gate-last” fabrication technique where the sacrificial gate electrode 214 is to be removed and a replacement gate structure is to be formed in its place. More specifically, as depicted in FIG. 2E, one or more etching processes are performed to remove the sacrificial gate electrode 214 and the sacrificial gate insulation layer 12 to define a gate opening 220. It should be understood, that, in forming the gate opening 220, the sacrificial gate insulation layer 12 may not be removed in all cases, i.e., the sacrificial gate insulation layer 12 may, in fact, be at least part of the gate insulation materials for the final replacement gate electrode structure of the device 200. However, in most cases, the sacrificial gate insulation layer 12 will also be removed at the time the sacrificial gate electrode 214 is removed.

Thereafter, as depicted in FIG. 2F, an illustrative replacement gate structure 230 is formed in the gate opening 220 using known techniques. In the illustrative example depicted in FIG. 2F, the replacement gate structure 230 is comprised of a high-k gate insulation layer 30A, a first metal layer 30B comprised of a metal, typically a work-function adjusting metal (e.g., a layer of titanium nitride), and a second metal layer 30C (e.g., aluminum). However, as will be recognized by those skilled in the art after a complete reading of the present application, the replacement gate structure 230 may be of any desired construction and comprised of any of a variety of different materials. For example, the replacement gate structure 230 may be comprised of more than the two illustrative metal layers 30B, 30C, and it may have more than the single insulation layer 30A depicted in the drawings. The conductive portions of the gate electrode structure 230 may also include non-metal materials, such as polysilicon. Additionally, the replacement gate structure 230 for an NMOS device may have a different material combination as compared to a replacement gate structure 230 for a PMOS device. Thus, the particular details of construction of replacement gate structure 230, and the manner in which such replacement gate structure 230 is formed, should not be considered a limitation of the present invention.

It should be noted that, considered collectively, the conductive portions of the replacement gate structure 230, i.e., the metal layers 30B, 30C in the illustrative example depicted herein, will be referred to as the replacement gate electrode 232. As can be seen in FIG. 2F, using the methods described herein, the replacement gate electrode 232 has a reentrant or inwardly-tapered cross-sectional configuration that corresponds to that of the sacrificial gate electrode 214 (FIG. 2D). Stated another way the width of the replacement gate electrode 232 at its bottom surface 232B is less than the width of the replacement gate electrode 232 at its upper surface 232U. In the illustrative example depicted in FIG. 2F, the sidewalls 232S of the replacement gate electrode 232 have a generally planar and tapered configuration.

After the point of fabrication depicted in FIG. 2F, additional processing operations are performed to complete the fabrication of the device 200. Such additional processing operations may include the formation of metal silicide regions (not shown) on the source/drain regions (not shown) of the device, the formation of self-aligned contacts (not shown) that are conductively coupled to the metal silicide regions, and the formation of additional metallization layers (not shown) above the device 200 using known techniques. Of course, the total number of metallization layers may vary depending on the particular device under construction.

As described above, using the techniques disclosed herein, the cross-sectional configuration of the sacrificial gate electrode 214 and the corresponding replacement gate electrode 232 of the replacement gate structure 230 may be modified as desired by controlling the distribution of the impurity or impurities 204 within the layer 202. The sacrificial gate electrode 214 and the corresponding replacement gate electrode 232 depicted above in FIGS. 2A-2F is but one example of the cross-sectional configurations that may be produced using the methods disclosed herein.

FIG. 2G depicts, from left to right, the illustrative sacrificial gate electrode 214, the corresponding replacement gate electrode 232 and a plot of the distribution of the impurity or impurities 204 in the layer 202. In this illustrative example, where the impurity or dopant 204 tends to increase the etch rate of the layer of material 202, the distribution of the impurity or impurities 204 within the layer of material 202 may be approximately linear with a lesser concentration of the impurity or impurities 204 being less (or perhaps zero) at the upper surface 202U and a greater concentration of the impurity or impurities 204 at the bottom surface 202B, as reflected by the solid line in FIG. 2G. In the alternative embodiment, where the impurity or dopant 204 tends to decrease the etch rate of the layer of material 202, the distribution of the impurity or impurities 204 within the layer of material 202 may be approximately linear with a lesser concentration of the impurity or impurities 204 being greater at the upper surface 202U and a lesser (or perhaps zero) concentration of the impurity or impurities 204 at the bottom surface 202B, as reflected by the dashed line in FIG. 2G. It should be understood that the difference in concentration of the impurity or impurities is relative in nature. Thus, a layer of material 202 having a concentration of the impurity or impurities 204 of approximately zero at the upper surface 202U and approximately 20% at the bottom surface 202B should etch approximately the same as a layer of material 202 having a concentration of the impurity or impurities 204 of approximately 10 at the upper surface 202U and approximately 30% at the bottom surface 202B.

FIG. 2H depicts, from left to right, another illustrative sacrificial gate electrode 214A, the corresponding replacement gate electrode 232A and a plot of the distribution of the impurity or impurities 204 in the layer 202 for the illustrative example where the impurity or dopant 204 tends to increase the etch rate of the layer of material 202. A corresponding plot of the impurity distribution where the impurity or dopant 204 tends to decrease the etch rate of the layer of material 202 is depicted by a dashed line in FIG. 2H. In this illustrative example, the distribution of the impurity or impurities 204 within the layer of material 202 may be non-linear, wherein the concentration of the impurity or impurities 204 varies throughout at least some portion of the thickness 202T of the layer of material 202. However, in general, for the illustrative example where the impurity or dopant 204 tends to increase the etch rate of the layer of material 202, the concentration of the impurity or impurities 204 at the upper surface 202U is typically less than the concentration of the impurity or impurities 204 at the bottom surface 202B. The converse is true where the impurity or dopant 204 tends to decrease the etch rate of the layer of material 202. In this illustrative embodiment, the sidewalls 214S of the sacrificial gate electrode 214A and the sidewalls 232S of the replacement gate electrode 232A have a curved or non-planar configuration.

FIG. 2I depicts, from left to right, yet another illustrative sacrificial gate electrode 214B, the corresponding replacement gate electrode 232B and a plot of the distribution of the impurity or impurities 204 in the layer 202 for the illustrative example where the impurity or dopant 204 tends to increase the etch rate of the layer of material 202. A corresponding plot of the impurity distribution where the impurity or dopant 204 tends to decrease the etch rate of the layer of material 202 is depicted by a dashed line in FIG. 2I. In this illustrative example, the distribution of the impurity or impurities 204 within the layer of material 202 may constitute a stepped, non-linear profile wherein the concentration of the impurity or impurities 204 varies throughout portions of the thickness 202T of the layer of material 202. However, in general, for the illustrative example where the impurity or dopant 204 tends to increase the etch rate of the layer of material 202, the concentration of the impurity or impurities 204 at the upper surface 202U is typically greater than the concentration of the impurity or impurities 204 at the bottom surface 202B. The converse is true where the impurity or dopant 204 tends to decrease the etch rate of the layer of material 202. In this illustrative embodiment, the sidewalls 214S of the sacrificial gate electrode 214B and the sidewalls 232S of the replacement gate electrode 232B have a generally stepped or non-planar configuration.

As those skilled in the art will recognize after reading the present application, the methods disclosed herein permit designers to tailor the shape or cross-sectional configuration of the replacement gate structure 230 and particularly the cross-sectional configuration of the sacrificial gate electrode 214 and the replacement gate electrode 232 used in a gate last manufacturing technique. The presently disclosed methods and devices may reduce one or more of the problems identified in the background section of this application.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a layer of material for a sacrificial gate electrode, said layer of material comprising at least one impurity that changes the etch rate of said layer of material as compared to an etch rate for said layer of material without said impurity, wherein a concentration of said at least one impurity varies along a direction that corresponds to a thickness of said layer of material;
performing an etching process on said layer of material comprising said at least one impurity to define a sacrificial gate electrode;
performing another etching process to remove said sacrificial gate electrode so as to at least partially define a gate opening in a layer comprised of insulating material; and
forming a replacement gate electrode in said gate opening.

2. The method of claim 1, wherein performing said etching process on said layer of material to define said sacrificial gate electrode comprises performing said etching process on said layer of material to define said sacrificial gate electrode with a width at a bottom surface of said sacrificial gate electrode that is less than a width of said sacrificial gate electrode at a location above said bottom surface.

3. The method of claim 1, wherein performing said etching process on said layer of material to define said sacrificial gate electrode comprises performing said etching process on said layer of material to define said sacrificial gate electrode with a reentrant profile.

4. The method of claim 1, wherein performing said etching process on said layer of material to define said sacrificial gate electrode comprises performing said etching process on said layer of material to define said sacrificial gate electrode with inwardly tapered sidewalls.

5. The method of claim 1, wherein performing said etching process on said layer of material to define said sacrificial gate electrode comprises performing said etching process on said layer of material to define said sacrificial gate electrode with non-planar sidewalls.

6. The method of claim 1, wherein said layer comprised of insulating material comprises at least one sidewall spacer and a deposited layer of material positioned adjacent said at least one sidewall spacer.

7. The method of claim 1, wherein said concentration of said at least one impurity varies linearly from a top surface of said layer of material to a bottom surface of said layer of material.

8. The method of claim 1, wherein said concentration of said at least one impurity varies non-linearly from a top surface of said layer of material to a bottom surface of said layer of material.

9. The method of claim 1, wherein forming said layer of material for a sacrificial gate electrode comprises performing a deposition process and introducing said at least one impurity during said deposition process.

10. The method of claim 1, wherein forming said layer of material for a sacrificial gate electrode comprises performing a deposition process to initially form said layer of material and, thereafter, performing one of an ion implantation process and a diffusion process to introduce said at least one impurity into said layer of material formed as a result of said deposition process.

11. The method of claim 1, wherein said at least one impurity comprises at least one of germanium, indium, arsenic, phosphorous, carbon and boron, or combinations thereof.

12. The method of claim 1, wherein said layer of material is comprised of at least one of silicon, doped silicon, silicon germanium and gallium arsenide.

13. The method of claim 1, wherein forming said replacement gate electrode comprises forming said replacement gate electrode comprising a plurality of metal layers.

14. The method of claim 1, wherein performing said etching process on said layer of material comprises performing a wet or dry etching process on said layer of material.

15. The method of claim 7, wherein said concentration of said at least one impurity increases linearly from a top surface of said layer of material to a bottom surface of said layer of material.

16. The method of claim 7, wherein said concentration of said at least one impurity decreases linearly from a top surface of said layer of material to a bottom surface of said layer of material.

17. The method of claim 1, wherein said impurity increases the etch rate of said layer of material.

18. The method of claim 1, wherein said impurity decreases the etch rate of said layer of material.

19. A method, comprising:
forming a layer of material for a sacrificial gate electrode, said layer of material comprising at least one impurity that increases the etch rate of said layer of material as compared to an etch rate for said layer of material without said impurity, wherein a concentration of said at least one impurity varies along a direction that corresponds to a thickness of said layer of material;
performing an etching process on said layer of material comprising said at least one impurity to define a sacrificial gate electrode having a reentrant profile;
performing another etching process to remove said sacrificial gate electrode so as to at least partially define a gate opening in a layer comprised of insulating material; and
forming a replacement gate electrode in said gate opening.

20. The method of claim 19, wherein said concentration of said at least one impurity increases from a top surface of said layer of material to a bottom surface of said layer of material.

21. A method, comprising:
forming a layer of material for a sacrificial gate electrode, said layer of material comprising at least one impurity that decrease the etch rate of said layer of material as compared to an etch rate for said layer of material without said impurity, wherein a concentration of said at least one impurity varies along a direction that corresponds to a thickness of said layer of material;
performing an etching process on said layer of material comprising said at least one impurity to define a sacrificial gate electrode having a reentrant profile;
performing another etching process to remove said sacrificial gate electrode so as to at least partially define a gate opening in a layer comprised of insulating material; and
forming a replacement gate electrode in said gate opening.

22. The method of claim 21, wherein said concentration of said at least one impurity decreases from a top surface of said layer of material to a bottom surface of said layer of material.
